(19) United States
(12) Patent Application Publication
(10) Pub. No.: US 2012/0214322 A1
(43) Pub. Date: Aug. 23, 2012

(54) USB INTERFACE DEVICE AND CIRCUIT BOARD THEREOF

(75) Inventors: JEFFREY SHUE JEN LU, Santa Clara, CA (US); PING-KUN LIN, Tu-Cheng (TW); CHUN-WEI LEE, Tu-Cheng (TW)

(73) Assignee: HON HAI PRECISION INDUSTRY CO., LTD., Tu-Cheng (TW)

(21) Appl. No.: 13/149,814

(22) Filed: May 31, 2011

(30) Foreign Application Priority Data
Feb. 18, 2011 (CN) 201110040718.X

(51) Int. Cl. H01R 12/71; H05K 1/11

(52) U.S. Cl. 439/78; 174/266

(57) ABSTRACT

An exemplary USB interface device includes a circuit board and a USB socket mounted on the circuit board. The USB socket includes a connecting port, a plurality of electrical pins and fixing pins extending from a side of the USB socket. The circuit board defines first and second inserting hole groups. The USB socket can be selectively inserted into the first or second inserting hole group according to the type of USB socket. When the electrical pins and the fixing pins of the USB socket are inserted into and fixed on the first inserting hole group of the circuit board, the second inserting hole group is standing idle. When the electrical pins and the fixing pins of the USB socket are inserted into and fixed on the second inserting hole group of the circuit board, the first inserting hole group is standing idle.

### BACKGROUND

1. Technical Field

The disclosure relates to a USB (Universal Serial Bus) interface device which has a circuit board compatible with different types of USB sockets.

2. Description of Related Art

USB interfaces are the most widely used computer peripheral interfaces. A USB interface generally includes a circuit board and a USB socket mounted on the circuit board. The USB socket includes a plurality of pins extending therefrom to connect the circuit board. However, the pins of different types of USB sockets are distributed over different positions. Different circuit boards need to be provided to match these USB sockets, resulting in increased manufacturing costs.

What is needed, therefore, is a USB interface device which can overcome the limitations described.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, like reference numerals designate corresponding parts throughout the views.

FIG. 1 is an isometric, assembled view of a USB interface device in accordance with an embodiment of the disclosure.

FIG. 2 is an enlarged, bottom plan view of the USB interface device of FIG. 1.

FIG. 3 is an exploded view of the USB interface device of FIG. 1.

FIG. 4 shows another USB interface device similar to the USB interface device of FIG. 1.

FIG. 5 is an enlarged, bottom plan view of the USB interface device of FIG. 4.

FIG. 6 is an exploded view of the USB interface device of FIG. 4.

### DETAILED DESCRIPTION

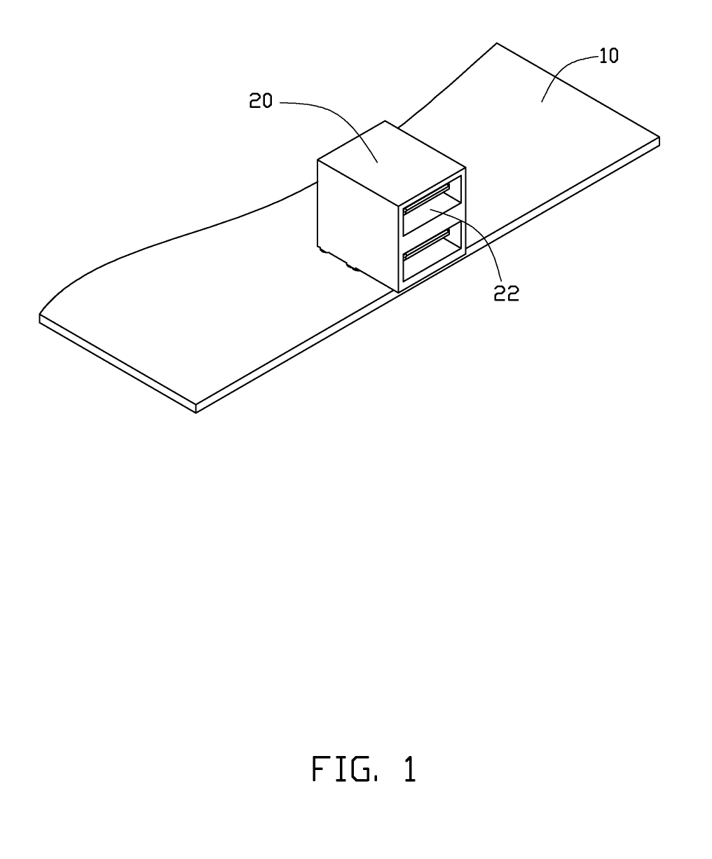

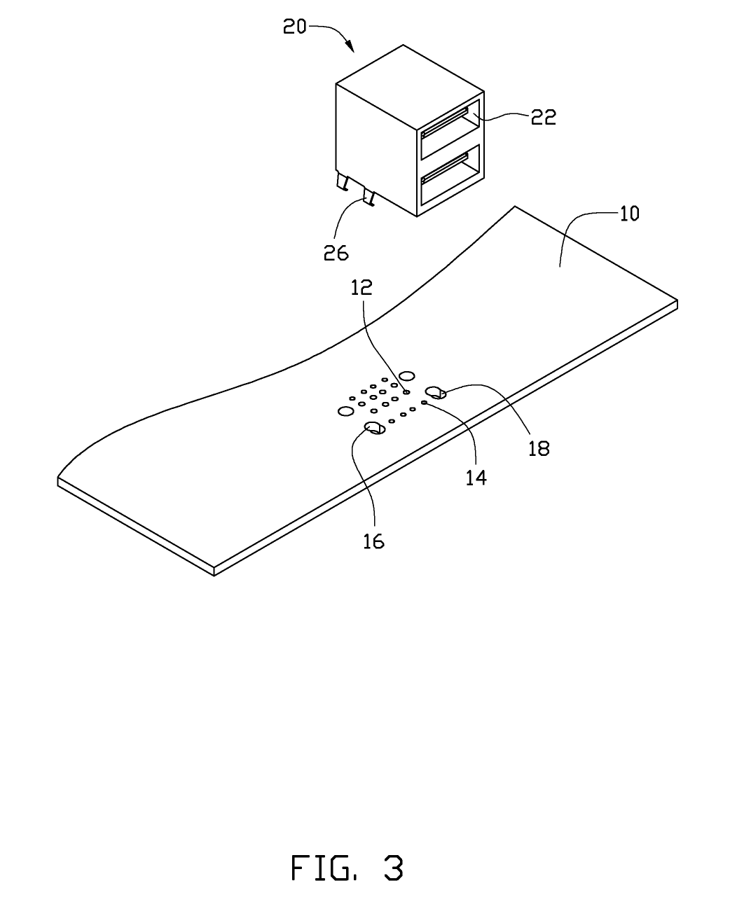

Referring to FIGS. 1-3, a USB interface device in accordance with an embodiment of the disclosure is shown. The USB interface device includes a circuit board 10, and a USB socket 20 mounted on the circuit board 10.

The USB socket 20 includes a bottom side, a connecting port 22, and eight inserting pins 24 and four fixing pins 26 extending from the bottom side. In this embodiment, the connecting port 22 is formed at a lateral side of the USB socket 20, which perpendicularly intersects the bottom side of the USB socket 20 from which the inserting pins 24 extend. The eight inserting pins 24 are arranged in two parallel lines. The four fixing pins 26 are located around four corners of the array of eight inserting pins 24. A dimension of each inserting pin 24 is smaller than that of each fixing pin 26. The connecting port 22 is for receiving a USB plug therein. The fixing pins 26 fix the USB socket 20 on the circuit board 10, and are electrically insulated from the circuit board 10. The inserting pins 24 are electrically connected to the circuit board 10.

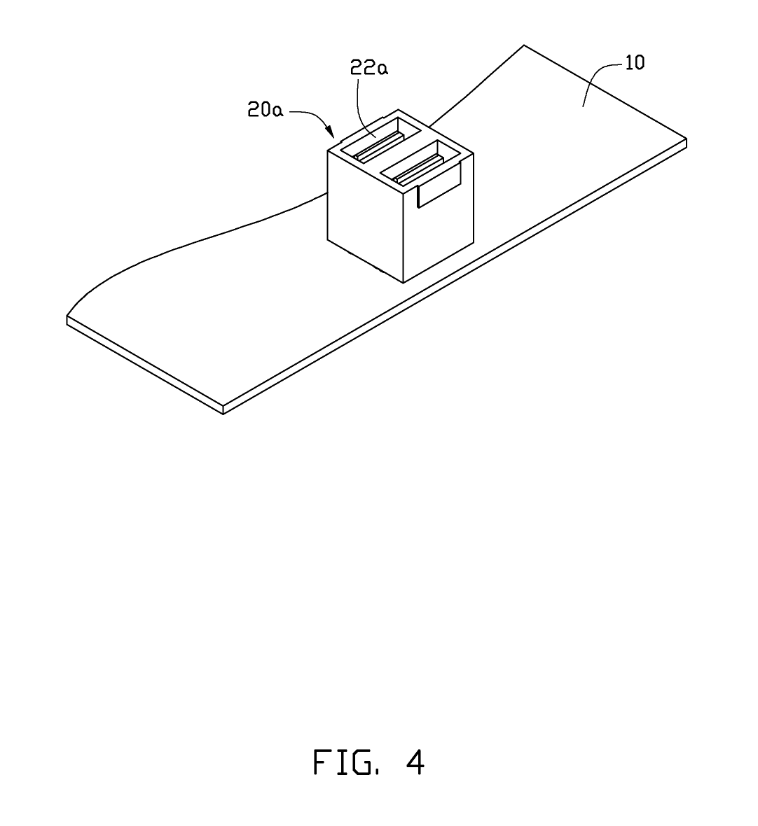

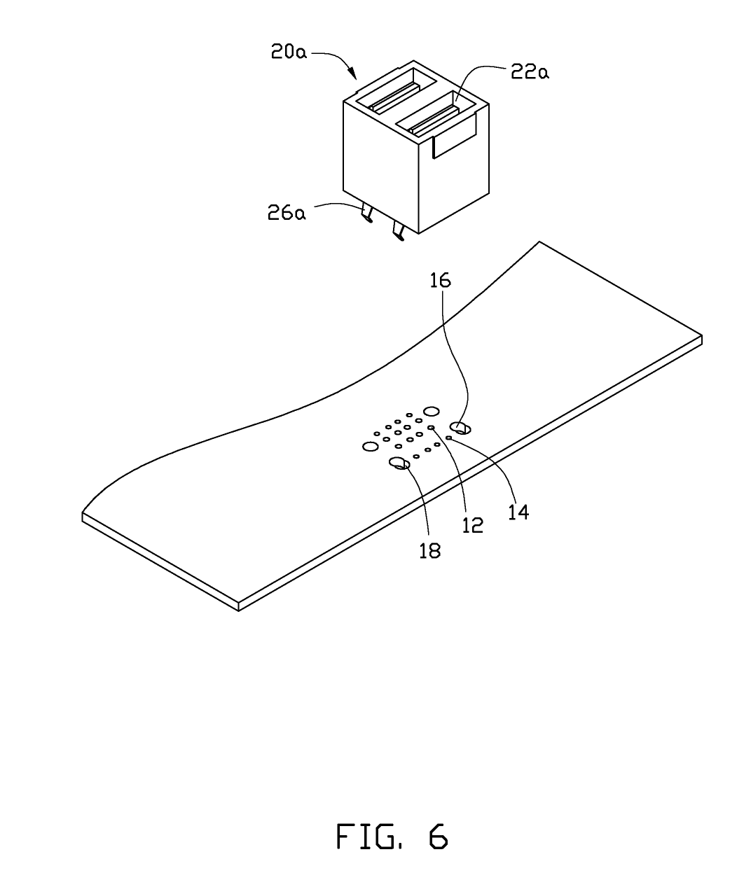

Referring to FIGS. 4-6, another USB socket 20a different from the USB socket 20 of FIGS. 1-3 is shown. The USB socket 20a includes a bottom side, a connecting port 22a, and eight inserting pins 24a and four fixing pins 26a extending from the bottom side. In this embodiment, the connecting port 22a is formed at a top side of the USB socket 20a, with the top side being parallel to the bottom side of the USB socket 20a from which the inserting pins 24a extend. The inserting pins 24, 24a and the fixing pins 26, 26a of each of the two USB sockets 20, 20a are distributed over different positions.

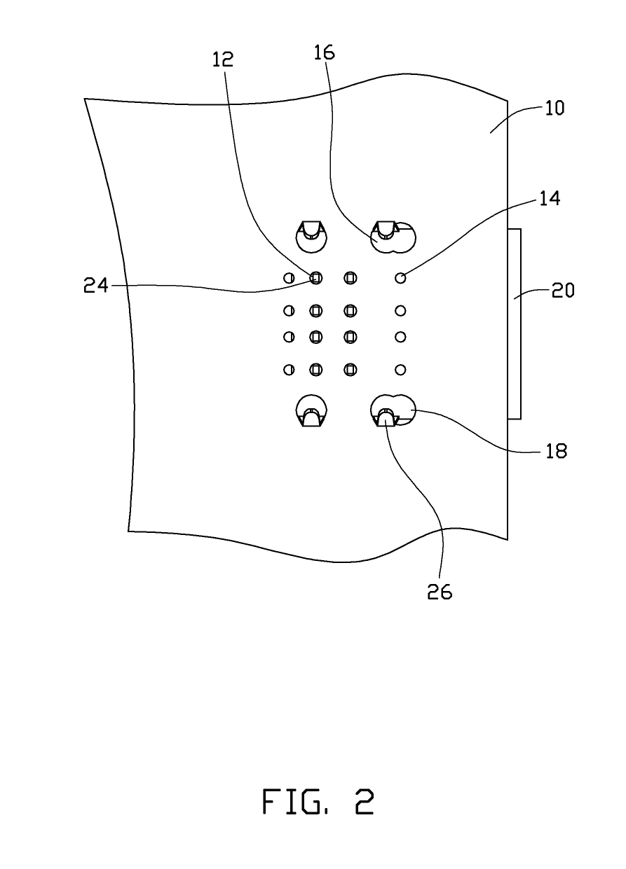

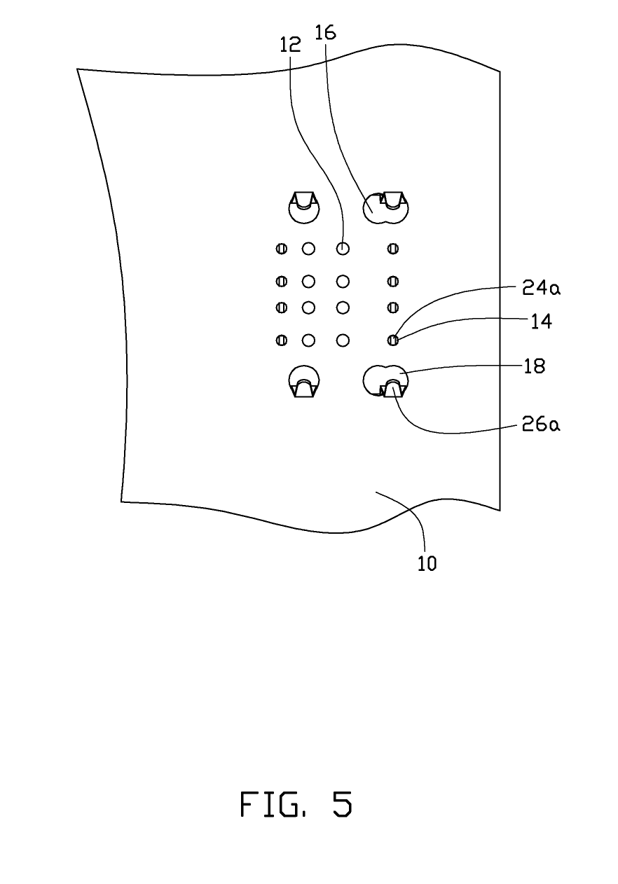

The circuit board 10 defines first and second inserting hole groups. Referring to FIGS. 2 and 5, the first inserting hole group includes eight first inserting holes 12 and four first fixing holes 16. The first inserting holes 12 and the first fixing holes 16 are all through holes. The eight first inserting holes 12 are arranged in two parallel lines, and the four first fixing holes 16 are located at two ends of the array of eight first inserting holes 12. Each first inserting hole 12 has a diameter smaller than that of each first fixing hole 16. The second inserting hole group includes eight second inserting holes 14 and four second fixing holes 18. The second inserting holes 14 and the second fixing holes 18 are all through holes. The eight second inserting holes 14 are arranged in two parallel lines, and the four second fixing holes 18 are located at two ends of the array of eight second inserting holes 14. Each second inserting hole 14 has a diameter smaller than that of each second fixing hole 18.

The first inserting holes 12 of the first inserting hole group are located between the two lines of second inserting holes 14 of the second inserting hole group. Two of the first fixing holes 16 of the first inserting hole group and two of the second fixing holes 18 of the second inserting hole group completely overlap in the circuit board 10. The other two first fixing holes 16 of the first inserting hole group and the other two second fixing holes 18 of the second inserting hole group do not completely overlap, yet partially overlap in the circuit board 10. The first inserting holes 12 are arranged corresponding to the inserting pins 24 of the USB socket 20, and the first fixing holes 16 are arranged corresponding to the fixing pins 26 of the USB socket 20 (shown in FIG. 2). The second inserting holes 14 are arranged corresponding to the inserting pins 24 of the USB socket 20a, and the second fixing holes 18 are arranged corresponding to the fixing pins 26 of the USB socket 20a (shown in FIG. 5).

Referring to FIG. 2, when mounting the USB socket 20 on the circuit board 10, the inserting pins 24 and the fixing pins 26 of the USB socket 20 are inserted into the first inserting hole group of the circuit board 10, and then the inserting pins 24 and the fixing pins 26 are fixed on the circuit board 10 by soldering.

Referring to FIG. 5, when mounting the USB socket 20a on the circuit board 10, the inserting pins 24a and the fixing pins 26a of the USB socket 20a are inserted into the second inserting hole group of the circuit board 10, and then the inserting pins 24a and the fixing pins 26a are fixed on the circuit board 10 by soldering.

According to the disclosure, the circuit board 10 of the USB interface device is compatible with two different types of USB sockets 20, 20a. Accordingly, the cost of manufacturing different USB interface devices with different types of USB sockets can be reduced.

In one alternative embodiment, the other two first fixing holes 16 of the first inserting hole group and the other two second fixing holes 18 of the second inserting hole group substantially do not overlap. In such case, each other first fixing hole 16 and the corresponding other second fixing hole 18 merely communicate with one another.

It is believed that the embodiments and their advantages will be understood from the foregoing description, and it will be apparent that various changes may be made thereto without departing from the spirit and scope of the disclosure or sacrificing all of its material advantages, the examples hereinbefore described merely being preferred or exemplary embodiments of the disclosure.

What is claimed is:

1. A Universal Serial Bus (USB) interface device comprising:
a circuit board defining first and second through hole groups; and
a USB socket mounted on the circuit board, the USB socket comprising a plurality of electrical pins and a plurality of fixing pins, the electrical pins and the fixing pins of the USB socket being inserted in a selected one of the first or second through hole groups of the circuit board.

2. The USB interface device of claim 1, wherein the first through hole group of the circuit board comprises a plurality of first inserting holes receiving the electrical pins of the corresponding USB socket therein, and a plurality of first fixing holes receiving the fixing pins of the corresponding USB socket therein, the first fixing holes being located at two ends of the plurality of first inserting holes.

3. The USB interface device of claim 2, wherein the second through hole group of the circuit board comprises a plurality of second inserting holes receiving the electrical pins of the corresponding USB socket therein, and a plurality of second fixing holes receiving the fixing pins of the corresponding USB socket therein, the second fixing holes being located at two ends of the plurality of second inserting holes.

4. The USB interface device of claim 3, wherein the plurality of first inserting holes of the first through hole group are located between the second inserting holes of the second through hole group.

5. The USB interface device of claim 3, wherein two of the first fixing holes of the first through hole group and two of the second fixing holes of the second through hole group completely overlap in the circuit board.

6. The USB interface device of claim 4, wherein another two of the first fixing holes of the first through hole group and another two of the second fixing holes of the second through hole group partially overlap in the circuit board.

7. The USB interface device of claim 1, wherein the fixing pins of the USB socket are electrically insulated from the circuit board.

8. The USB interface device of claim 7, wherein the electrical pins of the USB socket are electrically connected to the circuit board.

9. The USB interface device of claim 4, wherein the USB socket further comprises a bottom from which the fixing pins extend, and a connecting port, an opening of the connecting port of the USB socket is substantially perpendicular to the bottom of the USB socket, and the electrical pins and the fixing pins of the USB socket are fixed in the first through hole group of the circuit board.

10. The USB interface device of claim 4, wherein the USB socket further comprises a bottom from which the fixing pins extend, and a connecting port, an opening of the connecting port of the USB socket is substantially parallel to the bottom of the USB socket, and the electrical pins and the fixing pins of the USB socket are fixed in the second through hole group of the circuit board.

11. A circuit board comprising:
a first through hole group adapted for receiving electrical pins and fixing pins of a first type of USB socket; and
a second through hole group adapted for receiving electrical pins and fixing pins of a second type of USB socket different from the first type of USB socket.

12. The circuit board of claim 11, wherein the first through hole group comprises a plurality of first inserting holes arranged in two lines, the second through hole group comprising a plurality of second inserting holes arranged in two lines and located at two sides of the first inserting holes of the first through hole group.

13. The circuit board of claim 12, wherein the first through hole group further comprises a plurality of first fixing holes located at two ends of the first inserting holes of the first through hole group, the second through hole group further comprising a plurality of second fixing holes located at two ends of the second inserting holes of the second through hole group, the first fixing holes of the first through hole group and the second fixing holes of the second through hole group completely overlapping or partially overlapping in the circuit board.

14. The circuit board of claim 13, wherein each of the first and second inserting holes has a diameter smaller than a diameter of each of the first and second fixing holes.

15. A Universal Serial Bus (USB) interface device comprising:
a circuit board defining a plurality of inserting through holes and a plurality of fixing through holes;
wherein the inserting through holes are arranged in a matrix, and the fixing through holes are arranged at two opposite sides of a periphery of the matrix of inserting through holes;
the fixing through holes comprise two first fixing through holes at the two opposite sides of the matrix, respectively, and two second fixing through holes at the two opposite sides of the matrix, respectively;
the two first fixing through holes are substantially the same as each other, the two second fixing through holes are substantially the same as each other, and each of the second fixing through holes is larger than each of the first fixing through holes; and
each of the second fixing through holes defines a first area nearer to a corresponding first fixing through hole located at the same side of the matrix, and a second area farther from the corresponding first fixing through hole located at the same side of the matrix; and
a USB socket mounted on the circuit board, the USB socket comprising a plurality of electrical pins and a plurality of fixing pins;
wherein the USB socket is a selected one of a first type of USB socket and a second type of USB socket;
the first type of USB socket has the electrical pins thereof inserted in a first plurality of the inserting through holes, two of the fixing pins thereof inserted in the first fixing through holes, and another two of the fixing pins thereof inserted in the first areas of the second fixing through holes; and
the second type of USB socket has the electrical pins thereof inserted in a second plurality of the inserting through holes different from the first plurality of inserting through holes, two of the fixing pins thereof inserted in the first fixing through holes, and another two of the fixing pins thereof inserted in the second areas of the second fixing through holes.

16. The USB interface device of claim 15, wherein the first and second areas of each of the second fixing through holes partially overlap.

17. The USB interface device of claim 15, wherein the first and second areas of each of the second fixing through holes do not overlap but are in communication with each other.

18. The USB interface device of claim 15, wherein all the inserting through holes of the first plurality of inserting through holes are different from all the inserting through holes of the second plurality of inserting through holes.
